(19) United States
(12) Patent Application Publication
(10) Pub. No.: US 2011/0017280 A1
(43) Pub. Date: Jan. 27, 2011

(54) PARTIALLY TRANSPARENT SOLAR PANEL

(76) Inventor: Philip Thomas Rumsby, Bladon (GB)

Correspondence Address: KED & ASSOCIATES, LLP, P.O. Box 221200, Chantilly, VA, 20153-1200, US

(21) Appl. No.: 12/866,598

(22) PCT Filed: Feb. 6, 2009
(86) PCT No.: PCT/GB2009/000318

§ 371 Date: Oct. 13, 2010

(30) Foreign Application Priority Data
Feb. 7, 2008 (GB) 0802289.9

(51) Int. Cl. H01L 31/042

(52) U.S. Cl. 136/251; 219/121.71; 219/121.8; 219/121.7; 438/69

(57) ABSTRACT

A method is described for forming a partially transparent thin film solar panel by providing an array of unconnected holes in an opaque layer of the panel the holes being sufficiently small so that they are not discernable to the human eye and the light transparency factor caused by the holes being selectively controlled so that it can be graded in two dimensions by varying the size and/or spacing of the holes. A thin film solar panel with an opaque layer which is made partially transparent by providing an array of unconnected holes therein, the holes being sufficiently small so that they are not discernable to the human eye and the light transparency factor caused by the holes being graded in one or two dimensions by variations in the size and/or spacing of the holes is also described together with a laser ablation tool for forming such a panel, the tool comprising a laser, a scanner for scanning a laser beam relative to the panel, focussing means for focussing the laser beam on the opaque layer and control means for selectively controlling the laser repetition rate, the scanning speed, the pulse energy and/or the focussing of the laser beam whereby the light transparency factor caused by the holes can be graded in two dimensions by varying the size and/or spacing of the holes.

### TECHNICAL FIELD

This invention relates to a partially transparent solar panel and to a method and laser ablation tool for making the panel.

### BACKGROUND ART

Lasers have been used for many years for scribing and removing the thin layers used in solar panels to create and interconnect the sub cells and isolate the edge regions. The usual process of manufacturing solar panels based on thin film materials consists of the following steps:—
a) Deposit a thin layer of the lower electrode material over the whole substrate surface. The substrate is usually glass but can also be a polymer sheet. This lower layer is often a transparent conducting oxide such as tin oxide, zinc oxide or indium tin oxide (ITO).
b) Laser scribe parallel lines across the panel surface at typically 5-10 mm intervals right through the electrode layer to separate the continuous film into electrically isolated regions.
c) Deposit the electricity generating layer over the whole substrate area. This layer might consist of a single amorphous silicon layer or a double layer of amorphous silicon and micro-crystalline silicon.
d) Laser scribe lines through this layer parallel to and as close as possible to the initial scribes in the first layer without damaging the lower electrode material
e) Deposit a third, top layer, often a metal such as aluminium, over the whole panel area.
f) Laser scribe lines in this third layer as close to and parallel to the other lines to break the electrical continuity of the top electrode

This procedure of deposition followed by laser isolation breaks up the panel into a multiplicity of smaller separate cells and causes an electrical series connection to be made between all the cells in the panel so that the voltage generated by the whole panel is given by the product of the potential formed within each cell and the number of cells. Panels are divided up into 50-100 cells so that overall panel output voltage is typically in the 50 volt range. Each cell is typically 5-15 mm wide and around 1000 mm long. A thorough description of the standard laser processes used is given in JP10209475

Many electricity generating materials can be used to make thin film based solar panels. As well silicon based structures equally effective devices are made based on Cadmium Teluride (CdTe), Copper Indium diselenide (CIS), Copper Indium Gallium diselenide (CIGS) and crystalline silicon on glass (CSG). Films based on materials containing silicon nano-wires, doped and dye sensitized metal oxide nano-particles, CdSe quantum dots and nano-particle polymers are also emerging as solar panel active materials. Lasers are used to scribe some or all of the layers to form interconnects in many cases.

The lasers used generally operate in the infra-red (1064 nm wavelength) region of the spectrum as well as in the visible region (at the 2^{nd} harmonic) wavelength of 532 mm). Sometimes UV lasers are used. The lasers are generally pulsed with pulse lengths in the range of a few to several 100 nanoseconds and operate at pulse repetition rates in the range of a few kHz to few 100 kHz

For scribing some layers the laser beam is applied from the coated side of the substrate but for other layers it is best applied from the opposite side in which case the beam passes through the transparent substrate before interacting with the film. In particular for scribing lines in the electricity generating layer on top of a transparent electrode layer on a glass substrate, a laser operating in the centre of the visible light spectrum (such as a second harmonic Yag laser operating at 532 nm) is fired through the glass and lower electrode layer so that it interacts with the top electricity generating layer due to its high absorption. In this process the top layer is vaporised and removed leaving the lower electrode, layer undamaged. Such a process causes the optical transmission within the scribe region in the top layer to increase. This region ceases to transmit however when the whole substrate is subsequently coated with the top electrode layer which is usually metallic. In the laser scribe process which follows partial transparency is recovered. This laser process is used to divide up the top electrode layer and is carried out by sending the beam through the glass and lower transparent electrode to interact once again with the absorbing electricity generating layer. When this layer is vaporized and removed it carries the overlying metal layer with it so creating an optically transparent region. From this description it can be seen that a pulsed laser is the ideal tool for selectively removing the layers to create optically transparent regions.

In most cases, after the bottom conducting layer, the electricity generating layer and the top conducting layer have been applied to the glass or polymer substrate and interconnected as described above the finished panel is opaque and transmits no light except in the very narrow lines where all the opaque layers have been removed. Such a panel is not useful as a window since the degree of transparency is generally less than 1% and is too low to be useful.

If conventional building windows are to be replaced with glass based solar panels or flexible solar panels are to be applied to existing building window panes then it is essential that they have some higher degree of transparency. A transparency in the range 5 to 20% is regarded as necessary. This is presently achieved in two ways.

In one case, small opaque solar panels are used that are separated from each other in both axes in order to allow light to pass though the gaps. This method leads to a complex window structure that is unsightly and does not permit a continuous view to be obtained.

In another case, large opaque solar panels are made to be partially optically transmitting by laser scribing through the opaque layers in a similar way to that used for interconnecting the cells as described above. In order to obtain the required optical transparency, which is usually in the range 5 to 20%, multiple parallel laser scribes are made along the panel in the direction perpendicular to the interconnection scribes. In order to carry out such a process in a reasonable time it is necessary to minimize the number of scribes made and hence these scribes must be wide in order to allow the required optical transmission. Such wide scribes are readily visible. U.S. Pat. No. 6,858,461 teaches a process in which the scribe lines are in the direction perpendicular to the interconnect scribes. The lines may also be made on a graded pitch in order to vary the optical transparency in one dimension.

U.S. Pat. No. 5,254,179 also teaches a solar module made partially transparent by providing elongate grooves which extend transversely across the solar cells so as to avoid disturbing the paths of current flow lines within the cell.

U.S. Pat. No. 6,858,461 also describes the use of a laser to selectively remove parts of an opaque layer to form a logo or some other descriptive feature made up of a pattern of holes that are either joined up or separate.

U.S. Pat. No. 4,795,500 describes the use of regular arrays of circular, triangular, square, hexagonal and polygonal shaped holes through the opaque layers on a solar panel. Selective chemical etching of the opaque layers by a photolithographic process is used, which is slow, costly and environmentally harmful. A mask is used to define the hole pattern, so a new mask needs to be formed if it is desired to change the pattern.

The present invention seeks to overcome limitations of the prior art and to provide solar panels which are partially transparent and have far greater opportunities for providing aesthetic designs.

### DISCLOSURE OF INVENTION

According to a first aspect of the invention, there is provided a method for forming a partially transparent thin film solar panel by providing an array of unconnected holes in an opaque layer of the panel the holes being sufficiently small so that they are not discernable to the human eye and the light transparency factor caused by the holes being selectively controlled so that it can be graded in two dimensions by varying the size and/or spacing of the holes.

According to another aspect of the invention, there is provided a thin film solar panel having an opaque layer which is made partially transparent by providing an array of unconnected holes therein, the holes being sufficiently small so that they are not discernable to the human eye and the light transparency factor caused by the holes being graded in one or two dimensions by variations in the size and/or spacing of the holes.

According to a further aspect of the invention, there is provided a laser ablation tool for forming a partially transparent thin film solar panel by forming an array of unconnected holes in an opaque layer of the panel the holes being sufficiently small so that they are not discernable to the human eye, the tool comprising a scanner for scanning a laser beam relative to the panel, focussing means for focussing the laser beam on the opaque layer and control means for selectively controlling the laser repetition rate, the scanning speed, the pulse energy and/or the focussing of the laser beam whereby the light transparency factor caused by the holes can be graded in two dimensions by varying the size and/or spacing of the holes.

The invention thus enables a solar panel based on thin film materials deposited on glass or polymer substrates to be provided with a degree of transparency that can be varied continuously in two dimensions across the panel surface. Uniform partial transmittance allows the solar panels to be incorporated into buildings in the form of windows or roof lights so fulfilling their primary role of allowing a controlled amount of light to enter the building but at the same time generating electricity and the varying partial transmittance permits the panel to display an image or part of an image.

The features that provide the partial transparency and the image are sufficiently small so they are not discernable to the human eye. The following description gives examples of holes with a diameter of 0.1 mm and 0.15 mm. Holes of these sizes (and smaller) are sufficiently small so they are not discernable to the human eye. However, larger holes may still satisfy this requirement. Preferably, interconnect scribes used to separate adjacent cell of the panel are also not visible whereby an aesthetically pleasing panel can be provided in which all areas appear partially transparent (although to varying degrees).

Such panels can thus be readily integrated into buildings in the form of windows, awnings and roof lights and fully satisfy aesthetic requirements in terms of allowing the presentation of 2D half tone images.

This invention involves a method of modifying an opaque thin film solar panel in order to create partially transparent areas by means of a pulsed laser beam. The beam is focussed (or imaged) by a lens onto the coatings on the panel surface and continuously moved in a straight line at high speed in one direction across the surface of the solar panel in order to create a line of unconnected holes in the opaque coatings by the process of laser ablation.

The motion of the beam relative to the panel can be achieved by movement of the beam over a panel that is stationary in the direction of beam motion or alternatively the beam may be stationary and the panel is moved in that direction

Alternatively since the beam speed over the panel needs to be high, scanning mirror devices of either 2 axis type (eg galvo-mirror systems) or 1 axis type (eg polygon mirror units) can be used to move the beam over the panel surface.

Since the laser is pulsed the beam is emitted in a series of discrete bursts or pulses of radiation at a controllable repetition rate. Preferably, each individual laser pulse is capable, after focussing, of having sufficient energy to create a hole of a certain size in the opaque coatings used to make the solar panel. Therefore each pulse creates a small hole through which light can pass.

A key aspect of the invention is that the holes formed are isolated from each other and are always unconnected. This is achieved by control of the laser firing rate (repetition rate) and beam speed over the panel. Since the distance the beam moves between individual pulses is given by Δd=beam speed/repetition rate then the holes will remain unconnected so long as Δd is greater than the dimension of the hole-in the movement direction. This can be achieved by adjusting the beam speed to be greater than Δd×laser repetition rate or adjusting the laser repetition rate to be less than the beam speed/Δd. As an example consider the case where the laser is operating at a repetition rate of 10 kHz and each laser pulse creates a round hole of 0.1 mm diameter in the opaque films. In this case the beam speed needs to be maintained at a value above 1 m/sec in order to ensure that the holes do not touch. If a beam speed of 5 m/sec is used the repetition rate needs to be held at a value below 50 kHz to ensure that holes of 0.1 mm diameter remain unconnected

One of the most important preferred features of the invention is that the pitch of the holes formed by the laser can be changed while the beam is in motion over the panel. This is one of the ways in which the optical transmission factor is varied so that images can be created. Rapid changes in the hole pitch can be made to give graded or sudden changes in the optical transmission.

There are three ways to change the pitch of the holes created. In one method, the beam speed is held constant and the laser repetition rate is changed. In a second method, the laser repetition rate is held constant and the beam speed is varied. In the third method, both the beam speed and the repetition rate are changed together.

The pitch of the holes along the line of holes can be varied from the minimum value which just maintains the holes unconnected which is a distance just greater the hole width in the direction of motion right up to a value that is many times the hole diameter. In this way the panel transparency can be varied along the line length. As an example, for round holes of 0.1 mm diameter on a pitch of 0.3 mm, the linear transparency of the line is 26%. If the pitch is reduced to 0.12 mm, the transparency increases to 65%. The optical transparency can increase to close to 78% before the holes start to touch and interconnect.

The above discussion has only considered the case of linear motion of a beam over the panel surface creating holes in a single line. In practice, it is necessary to form a 2D array of holes so that motion of the beam relative to the panel in a direction orthogonal to the line-is also necessary. This can be achieved by movement of the laser beam in the direction perpendicular to the line of holes over a panel that is stationary or alternatively the beam can be held stationary in the direction perpendicular to the line of holes and the panel moved in that direction.

The relative motion of the beam and panel in the direction perpendicular to the line of holes can be either in step mode or can be continuous. Step motion of the beam or panel is required if the laser is delivered to the panel directly without use of a scanner system. In this case, a single line of holes is created and then the panel or beam is stepped in the direction perpendicular to the line to create a series of parallel lines of holes.

In the case that a 2D scanner unit is used, the scanner first axis is used to move the beam in a primary direction then the panel can be moved continuously in the orthogonal direction. In this case, the second motion axis of the scanner unit is used to cause the beam to follow the movement of the panel direction during each primary axis scan and at the end of each scan is used to move the beam quickly to the start position of the next line of holes. Such an arrangement leads to short process times for the whole panel area as the large number of steps made by the panel is avoided.

This arrangement is preferred as it gives most flexibility in positioning of the holes. The pitch along the beam scan direction can be changed by rapid changes in beam scan speed using the first motion axis of the scanner. The pitch between lines of holes can be changed rapidly by adjusting the start position of each new line of holes using the second motion axis of the scanner. In addition, the second motion axis of the scanner can be used to make secondary small movements of the beam in the panel motion direction while the beam is scanning in the primary direction such that the line of holes created is not straight and some holes are offset from the primary line axis. This secondary motion can be regularly repeating to create a line of holes that oscillates around a straight line or can be random. Examples of regularly repeating oscillations about a centre line are sinusoidal patterns or saw-tooth patterns of holes. Many other repeating patterns are also possible. This arrangement, where the secondary scanner axis is used to change the line from straight to some other form, allows holes to be positioned at virtually any position with respect to other holes in the same line or to holes in other lines.

In both cases described above the pitch of the holes in the panel in the direction perpendicular to the lines of holes is varied to change the panel optical transparency in that direction. A key feature is that the pitch between lines of holes can be adjusted during the process to enable gradual or sudden changes in optical transmission.

The pitch of the lines of holes can be varied from the minimum value which just maintains the holes in one line unconnected from those in another which for a rectangular 2D array of holes is a distance just greater the hole width in the direction perpendicular to the lines of holes right up to a value that is many times the hole diameter. In this way the panel transparency can be varied in the direction perpendicular to the line length.

As an example, for the case of a rectangular 2D array of round holes of 0.1 mm diameter on a pitch of 0.3 mm along the line and a similar value between lines, the area transparency is 8.7%. If the pitch in both directions is reduced to 0.15 mm and 0.12 mm, the area transparencies increase to 35% and 54.5% respectively. The optical transparency can increase to close to 78% for this 2D rectangular array before the holes start to touch and interconnect.

Because the instant at which the laser is fired as the beam is moved along a line over the panel surface is accurately controlled it is possible to position the holes in one line at any desired position with respect to holes in an adjacent line. This means that as well as rectangular 2D arrays of holes it is possible to make any other regular array such as triangular, hexagonal, etc.

For the case of a triangular array of round holes, very high optical transparencies are possible. For 0.1 mm diameter holes in a triangular array with 0.15 mm and 0.12 mm between hole centres the optical transparencies are 40% and 63% respectively. The optical transparency can increase to close to 90% for a triangular array before the holes start to touch and interconnect.

A key feature is that, because of the complete control of the laser firing time and corresponding hole position, it is also possible to make irregular or random 2D arrays where the holes in each line have no regular pitch and the pitch between lines is also irregular. This feature permits much greater flexibility in terms of creating aesthetically pleasing images with half tone appearance on the solar panel.

Changing the 2D pitch of holes of identical size is just one way of changing the optical transparency of the solar panel. Another method can be used which involves changing the size of the holes. Hole size changes can be used with the hole pitch held constant by firing the laser at constant repetition rate but consideration must always be given to the process parameters to ensure holes do not interconnect. This means that the hole size limit (Dmax) in the beam movement direction is given by:

Dmax=beam speed(v)/repetition rate(Hz).

As an example, for a beam speed of 5 m/sec and a laser repetition rate of 100 kHz, the maximum hole size possible before holes interconnect in the beam movement direction is 0.05 mm. A combination of hole size change and hole pitch change in one or both axes can also be used to control panel transparency in a very flexible way.

The size of the hole created by the laser pulse in the opaque films can be changed by two methods. In one case the energy in the laser pulse is changed. In the other case the laser spot size is changed. This latter operation can be accomplished by two different methods.

For the case where a change in energy is used to change the hole size, the optical system used is the simplest possible and the beam from the laser is focussed on the coatings on the panel surface by a lens system. In this case, the spot usually has a circular (round) shape and the distribution of energy within this focal spot is axi-metrically symmetric but is very non-uniform with a peak in the centre falling to a low level around the perimeter. Such a beam profile is usually referred to as a Gaussian profile.

Since there is usually a clearly defined threshold energy density at which the laser pulse will cause the opaque films to be removed, it is possible to use the non uniform beam profile to control the hole size. If the energy in the pulse is low and the energy density in the centre of the spot at the peak of the distribution is below the threshold for film removal, then no hole will be created. As the energy in the spot is increased so the energy density at the peak will exceed the threshold and a small hole will be made. As the energy in the spot is increased, the size of the region where the energy density exceeds the threshold increases and so the hole created in the opaque films increases. Hence, larger and larger hole sizes can be created by using more and more energy in the spot until a limit is reached set by unacceptable damage being caused to the solar panel substrate or the lower transparent electrode by the high energy density in the central peak of the spot. Adjustment of the energy in the laser pulse is achieved by control of the level of pulses emitted by the laser or by adjustment of a variable attenuator unit situated after the laser aperture.

The damage associated limitation on increase in spot size caused by increasing only the energy in the spot can be overcome by using a system where the size of the spot created on the panel surface can be changed. This can be achieved in two ways. One way uses the same simple optical system with a beam focussing lens as described above but the position of the focal plane is moved along the direction normal to the panel surface so that the spot size increases. The other way uses the lens in an imaging mode so that the reduced image of an aperture situated before the lens is projected onto the panel and control of the spot size is achieved by control of the aperture size.

In the first of these two methods, where the lens is used in focussing mode, a controllable telescope system is placed before the lens and the beam focal plane is caused to move above or below the panel surface by rapid adjustment of the separation of the telescope components. Such controllable separation telescope systems are well known and can move the focal plane very rapidly in the beam direction so changing the spot size on the panel surface. For example, if a telescope consisting of a negative lens of focal length of 125 mm and a positive lens of focal length 150 mm is placed in front of a focussing lens with focal length of 250 mm and a beam of 4 mm diameter and a wavelength of 532 nm passed through the optical system, then axial movement of only 1 mm of the negative telescope lens causes the spot size at the focal plane of the lens to increase from a minimum value of about 0.04 mm diameter to about 0.09 mm diameter. A further movement of 1 mm increases the spot size to almost 0.15 mm.

Such small telescope optics movements can be accomplished in fractions Of a millisecond with appropriate motors and controls so that significant changes in the spot size on the panel can be made within a few laser pulses as the beam moves over the panel thus allowing sudden and controlled graded changes in optical transparency over short distances.

If the energy in the laser pulse is held constant then increase of spot size on the panel leads to reduced overall energy density and the area of the spot that exceeds the energy density needed to remove the opaque film reduces and the hole decreases in size rather than increases. Hence, as the spot size is increased by movement of a telescope component, it is imperative that the energy within the pulse is increased to maintain the energy density at a constant level. A doubling of the spot diameter requires a four-fold increase in energy in the pulse. This is achieved by direct electronic control of the level of pulses emitted by the laser or by adjustment of a variable attenuator unit situated after the laser aperture.

The alternative way to control the laser spot size on the panel involves using the lens in an imaging rather than focussing mode. In this case, the panel is positioned at a distance from the lens that it somewhat longer than the distance to the beam focus. At this plane the spot on the panel is a reduced image of an object plane in the beam before the lens. The distances from the lens of the two conjugate planes are given by the well known formula:

1/u=1/f−1/v

where u is the distance from the lens to the upstream object plane, v is the distance from the lens to the downstream image plane and f is the focal length of the lens. The spot created at the image plane is reduced by a factor of u/v compared to the size at the upstream object plane.

By using such an imaging system the size and shape of the spot at the image plane can be defined and controlled by adjustment of the size and shape of the beam at the upstream plane. This is highly relevant in several ways. Firstly, by placing an aperture in the beam at the object plane the profile of the laser beam in the spot at the panel can be made to have a more uniform energy density as the aperture can be set to obscure the low power peripheral regions of the beam. A laser spot with higher uniformity generally gives improved process performance in terms of creating sharper more well defined edges to the holes created in the opaque layers on the solar panel.

A second, more important aspect is that apertures that are of any arbitrary shape can be inserted in the upstream object plane so that laser spots on the panel of any desired shape can be created. This allows holes in the opaque coatings on the panel of any arbitrary shape to be made. Circular, triangular, square and hexagonal shapes are examples of holes that can be used.

A third reason why an imaging system is important is that it can be used to control the size of the spot. If a dynamically adjustable aperture is used at the upstream image plane, the size of the spot on the panel can be changed while the beam is in motion across the panel surface. Such a method of changing spot size requires that the energy in the spot be adjusted as the aperture size is changed in order to keep the energy density in the spot constant. As discussed above, this can be accomplished by direct electronic control of the energy level of the pulses emitted by the laser or by use of an external variable attenuator unit.

There exists a variety of optical devices for improving the uniformity of laser beams. These devices may be based on the use of mirrors, lenses, prisms or diffractive optical elements but the result in all cases is similar in that a beam that has a more uniform profile is created at some downstream plane. The beam may also be re-shaped. Transformation of a round beam to a square beam is common. If such a device is used and the output plane of the device made to be coincident with the object plane of the imaging system used to create the spot on the panel then the spot shape and profile achieved on the panel may be of adequate quality in this case so that use of an aperture at the object plane is unnecessary.

It is possible to use a single laser beam to make holes over a large area solar panel but in the case where the panel is large and a large area of the solar panel requires holes to be made in order to create a large area image or allow optical transparency over the full panel area it is likely that in the interests of speed more than one laser beam will be used. As an example, if a solar panel that has a size of 1.3×1.1 m and it is required to make a rectangular array of round holes of 0.15 mm diameter on a pitch of 0.3 mm over the whole area in order to achieve an optical transparency of about 20% then the total number of holes is almost 16 million and the total length of the lines of holes to be made is about 5 km. If it is required to complete this operation in a reasonable time such as 100 seconds then if a single laser beam is used the beam would have to be moved at 50 m/sec which is unacceptably fast to maintain accuracy and control. Hence, it is likely that several laser beams will be used in parallel in order to reduce the beam speeds to acceptable levels.

In the case above, four laser beams operating in parallel would mean that an average beam speed of 12.5 m/sec would be required which is still excessive in terms of mechanical movement of a lens system over the panel or movement of the panel under the lens but is well within the reach of optical scanner units based on 2 axis galvanometer driven mirror systems or 1 axis rotating polygon mirror systems. Such units are preferably used in conjunction with appropriate lens systems. Hence, it is envisaged that this invention will typically be implemented by the use of multiple scanner type units operating in parallel on the surface of the solar panel. Depending on the film ablation process requirements, one or more lasers will be used to feed the multiple scanner units.

The use of a single 2 axis scanner unit to move a laser beam, at high speed over the full width of a 600 mm wide solar panel has been disclosed in U.S. Pat. No. 6,919,530 but this is for scribing interconnects where the requirement is to ensure that laser pulses overlap and the pitch of the scribes is several mm. In the present case, the panels are typically much larger, the holes created by the laser pulses should not overlap and the pitch between the lines of holes is much smaller so multiple scanners will be required to achieve acceptable process times and beam speeds.

The multiple scanner units can be disposed in a line parallel to one edge of the panel such that each scanner makes lines of holes that extend the full width of the panel and each scanner covers a fraction of the panel length. Alternatively, the scanners can be arranged in an array with each scanner making lines of holes across a fraction of the panel and covering a fraction of the panel length. A convenient way to organize the multiple scanners is in a line parallel to the direction in which the beam moves. In this case, the length of the beam scan region generated by the scanner unit is limited to a fraction of the total line length required to cover the full width of the panel. The consequence of this is that multiple lengths of lines of holes that are shorter than the panel width are needed to build up the full lengths of the lines. This means that as well as the beam motion by the scanner unit, motion of the substrate in at least one further axis with respect of the scanner units is required in order to cover the full area.

As an example consider two cases where a panel with dimensions 600×1200 mm is required to be perforated uniformly with holes of 0.1 mm diameter on a pitch of 0.3 mm in both directions. In this case, about 4000 lines parallel to the short edge of the panel are required. In the first case, the panel is processed with two 1D scanner units each having a scan length of one quarter of the panel width of 150 mm. The scan heads are separated by 300 mm and the process consists of stepped movement of the panel relative to the scan heads in the direction perpendicular to the line direction after each scan has been carried out in order to generate lines of holes over two separated bands each with a width of 150 mm. After movement of the panel over the full length of 1200 mm, the panel (or carriage holding the scanners) is stepped in the direction parallel to the line direction by the width of the band and the process is repeated. After two such passes, the full area of the panel has been covered. Exact overlap of the ends of the lines of holes in one band with the adjacent band is of course essential to have continuous lines of holes. In this case two axes of motion of the scanners with respect to the panel are needed

In the second case, the panel is processed by four 1D scanner units each having a scan length of one quarter of the panel width of 150 mm. The scan heads are separated by 150 mm and the process consists of stepped movement of the panel relative to the scan heads in the direction perpendicular to the line direction after each scan has been carried out in order to generate lines of holes over four interconnecting bands each with a width of 150 mm. After movement of the panel over the full length of 1200 mm the full area of the panel has been covered. In this case, only one axis of motion of the panel with the scan heads is required

The process of stepping the panel after each line scan makes the time taken to process the whole panel rather long as many thousand steps may be required. To overcome this limitation it is more usual to use double rather than single axis scanner units as described in U.S. Pat. No. 6,919,530 in which case the panel can be moved continuously and the additional scanner axis used to move the beam to follow the panel motion during hole formation and to perform a rapid beam fly-back to position the beam correctly on the moving panel for the start of another line scan.

Lines of holes can also be made on a moving panel by use of a high speed rotating polygon mirror. If correctly designed such a device can have a very fast fly-back time so that lines can be placed very close to each other and the pitch between lines changed by selection of the appropriate polygon mirror facet selected. Polygon scanners are limited in that rapid changes of beam speed are difficult to achieve and continuous variations in the pitch between lines cannot be made and hence the preferred scanner use in this invention is a 2D mirror type unit.

One key advantage of the multiple scanner arrangement described above is that by limiting the scan length to a fraction of the panel width it is possible to use scan lenses with relatively short focal length and hence smaller spot sizes and high accuracy spot positioning are more readily achievable. In addition, short focal length lenses are more appropriate if an imaging mode of optical operation is used

Another major advantage of this arrangement is that by adding further scanner units it is readily scalable to much larger panel sizes. This is not possible in the type of full width scanning described in U.S. Pat. No. 6,919,530 as accurate control of spot size and position with field sizes up to 1 m or more is very difficult.

As an example of how this 2D scanner based perforation technique can be scaled up to process larger panels consider the case of a 2.2×2.4 m solar panel where a uniform array of 0.1 mm diameter holes on a 2D pitch of 0.2 mm in the scan direction by 0.3 mm in the orthogonal direction is required in order to give an optical transparency of about 15%. In this case, eight parallel scanner units are used with each scan unit fed by a single laser using a fraction of the beam from a master laser. The scanners are mounted on a gantry above the panel and the scanners are spaced at one eighth of the panel width, in this case 275 mm. Each scanner can create a line of holes over a length of just over 275 mm. The panel is mounted on a single axis stage so it can be moved in the orthogonal direction to the gantry. In this case, the panel is processed in a single pass under the row of scan heads. Each of the 8 laser beams is fired at a repetition rate of 75 kHz and moved at a speed of 15 m/sec across each 275 mm long line to create holes every 0.2 mm. The panel moves continuously at a speed of 15 mm/sec and the whole panel is processed in a time of 160 sec.

In the above example, the use of eight scan heads has only been taken to illustrate the process. Any number of scan heads, from one to eight or even, more, is possible depending on the panel size and process time requirements. In addition, the use of a scan line length of 275 mm is only used to illustrate the process. Any scan line length, or width of band, is possible depending of process requirements. In general, where high accuracy hole positioning and aperture imaging is used to create a shaped, sharp edged spot a short focal length lens is used and the line length in each band is generally less than 200 mm. In situations where a focussed spot can be used and hole positioning accuracy requirements are not so high, a longer focal length lens can be used and line lengths up to 300 mm or more are possible.

An important point of this invention is that images can be created on the solar panel by changing the optical transmission in 2 dimensions. In the case where multiple scanners are used then each unit has a separate control system so that the pitch of holes in the scanning direction is independently adjustable. In addition, the energy level in each of the multiple beams is independently adjustable to allow independent hole size changes. Each scanner then creates its own part of the final full panel image.

In all the examples given above the laser beam or beams are incident from above on to the upper, coated, side of the panel. This is not an exclusive arrangement and other arrangements are equally possible. The beams may be incident from above and the panel may be arranged with the coated side facing downwards. Alternatively, the scanner units may be positioned below the panel with the beams directed upwards with the panel having its upper or lower surface coated.

Many different ways of effecting the required relative motion between panel and the scan heads are possible. The panel can remain stationary during processing with the scanners moving in 1 or 2 axes by means of a moving gantry over the panel. Alternatively, the scanners can be held stationary and the panel caused to move in 1 or 2 axes. Thirdly, the panel can move in one axis and the scanners move in the orthogonal axis if required.

Mounting the panel horizontally is also not an exclusive arrangement. The present invention can operate with the panel held vertically or even at some angle to the vertical. In this case, movement of the panel in the horizontal direction and movement of the scanners in the vertical direction is a practical arrangement.

When making a partially transparent solar panel by scribing lines or forming arrays of holes in the opaque coatings care has to be taken to ensure that no significant electrical shunts are formed that can degrade the performance of the solar panel. A shunt is a defect that creates a lower resistance electrical path where the resistance should be high. Such shunts can occur across the semiconductor layer between the top and bottom electrodes at the edges of the scribe lines or perimeters of the holes and can lead to reduction in panel efficiency. The risk of shunt formation is higher where multiple small holes are used rather than linear scribes to create a given level of transparency as the total length of edge created is much greater for the holes. For example, a transparency of approximately 10% can be created by forming an array of 0.18 mm diameter holes on a rectangular pitch of 0.5 mm or by scribing a 0.5 mm wide line every 5 mm. In these cases, the total length of the perimeters of all the holes is approximately six times greater than the length of the scribe edges so the risk of shunting is correspondingly greater. However, such shunts arise if inappropriate laser parameters are used for removing the opaque layer and can be avoided eg by use of short laser pulse length (eg a few tens of nanoseconds or less) to help avoid thermal diffusion at the edges of the holes and a spatial profile that provides a sharp edged hole (eg a top hat profile)

This potential problem is also reduced if the transparency is relatively modest (eg less than 20%), the holes are relatively small and regions are provided in each cell that have a lower hole size and/or density to compensate for areas of the cell that have a larger hole size and density. However, If much higher transparency is required, it may be better to provide this with a lower density of larger holes rather than a high density of very small holes

For a solar panel to operate most efficiently it is important that each of the series interconnected cells is balanced with the other cells having similar resistance and electrical performance. This means that when making panels that are partially transparent by removing areas of the opaque coatings it is important to ensure that the total areas removed from each cell within a single panel are similar. This is obviously easily achieved when the partial transparency is created by scribing parallel lines in the direction perpendicular to long axis of the cells and their interconnecting scribes as each cell will be scribed in a similar manner. However, when partial transparency is provided in the manner described above where the size and pitch of these holes is varied from one cell area to another cell area in order to create 2D halftone images care has to be taken to ensure that the cells are balanced. This can be achieved by controlling the operation of the laser, scanner and stages (eg by suitable software) such that the size, pitch and placement of individual holes within each cell are adjusted so that a 2D halftone image is formed that covers multiple cells whilst at the same time maintaining the total area of the holes created within each cell at the substantially the same level. By this means, the resistance of the cells remains balanced and electrical performance of the overall solar panel is not compromised. The ability to vary the sizes and spacing of the holes formed thus not only enables half tone images to be formed but also enables these to be formed in a manner that allows the total area of the holes within each cell to be carefully controlled.

When a half tone image extends across a plurality of the cells it is also possible to compensate for the differences between cells by providing additional transparency, eg in areas away from the image, in cells on which darker and/or fewer parts of the image lie so that the electrical performance of each cell is substantially similar.

Whilst, it is preferred that the electrical performance of each cell is substantially similar, in some cases it is sufficient to ensure that the variation in the electrical performance of each cell is within a predetermined range (eg with a maximum of 10% variation between cells).

Other preferred features of the invention will be apparent from the following description and from the subsidiary claims of the specification.

### BRIEF DESCRIPTION OF DRAWINGS

Exemplary embodiments of the invention will now be described, merely by way of example, with reference to the accompanying drawings of which:

FIG. 1 is a schematic view of apparatus illustrating a simple way of creating lines of holes in the opaque coatings on a solar panel suitable for us in the invention;

FIG. 2 is a similar schematic view where a single scanner unit with lens is used to move the beam to create rows of holes in the panel coatings;

FIG. 3 is a schematic view similar to FIG. 2 where two scanner and lens units are used;

FIG. 4 is a schematic view similar to FIG. 3 where only one axis motion of the panel is required;

FIG. 5 shows an enlarged plan view of some hole patterns that can be created in the panel coatings using the invention;

FIG. 6 shows an enlarged plan view of a further example of some of the hole patterns that can be created in the panel coatings;

FIG. 7 is a graph showing the pulse energy density profile in a focussed laser beam suitable for use in the invention;

FIG. 8 is a schematic view of a telescope arrangement for controlling the position of the beam focus with respect to the substrate surface suitable for use in the invention;

FIG. 9 shows an enlarged plan view of another example of hole patterns that can be created using the invention;

FIG. 10 shows an enlarged plan view of a pattern of square holes that can be created using the invention; and

FIG. 11 is an illustration of a half tone image that can be formed using a pattern of holes by means of the invention.

### DETAILED DESCRIPTION OF DRAWINGS

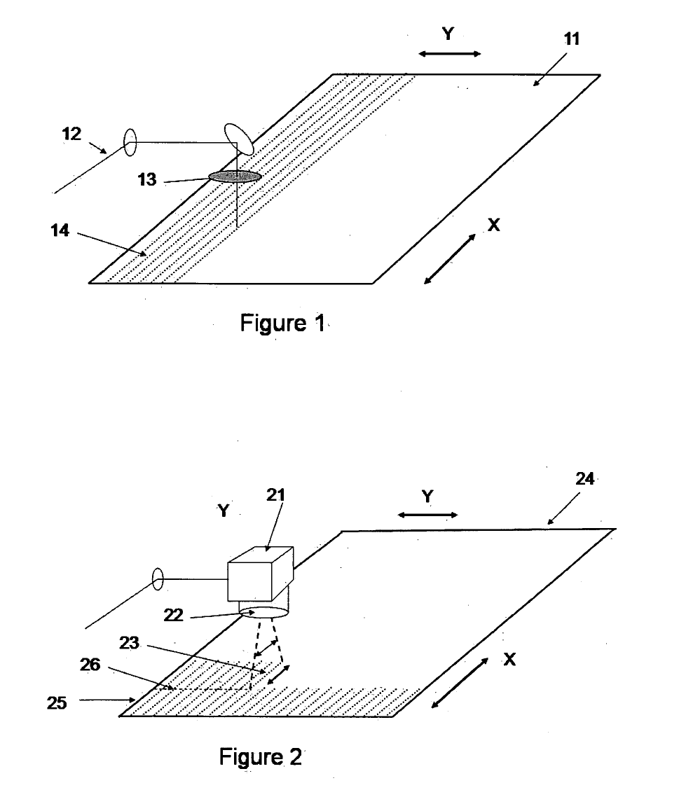

### FIG. 1

FIG. 1 shows a simple way of creating lines of holes in the opaque coatings on a solar panel 11. In this case the laser beam 12 is focussed with a stationary lens 13 on the surface of the panel which is moved continuously in the X direction with the laser firing to make a single row of holes 14. After the row, is completed the panel is stepped in the Y direction and another row of holes made parallel to the first rows of holes. This process repeats until the whole panel area or a desired part of the panel area has been covered with holes.

### FIG. 2

FIG. 2 shows the case where a single stationary 2 axis scanner unit 21 with lens 22 is used to create the lines of holes 23 on a panel 24 that is moving continuously. In this case, one motion axis of the scanner unit is used to move the beam in the X direction creating a row of holes that in the case shown extend over only a fraction of the width of the panel. The second motion axis of the scanner unit is used to cause the beam to follow the movement of the panel in the Y direction during each X scan and at the end of each X scan is used to move the beam quickly to the start position of the next line of holes. The movement of the panel in the Y direction under the scanner causes a band of lines of holes 25 to be formed over the full length of the panel. After each band is completed the panel is stepped in the X direction by the width of the band to allow an adjacent band to be formed. The process repeats until the full area or some selected part area of the panel area has been covered with holes. Accurate control of the scanner, laser and stages allows the rows of hole to join seamlessly at the interface between bands 26

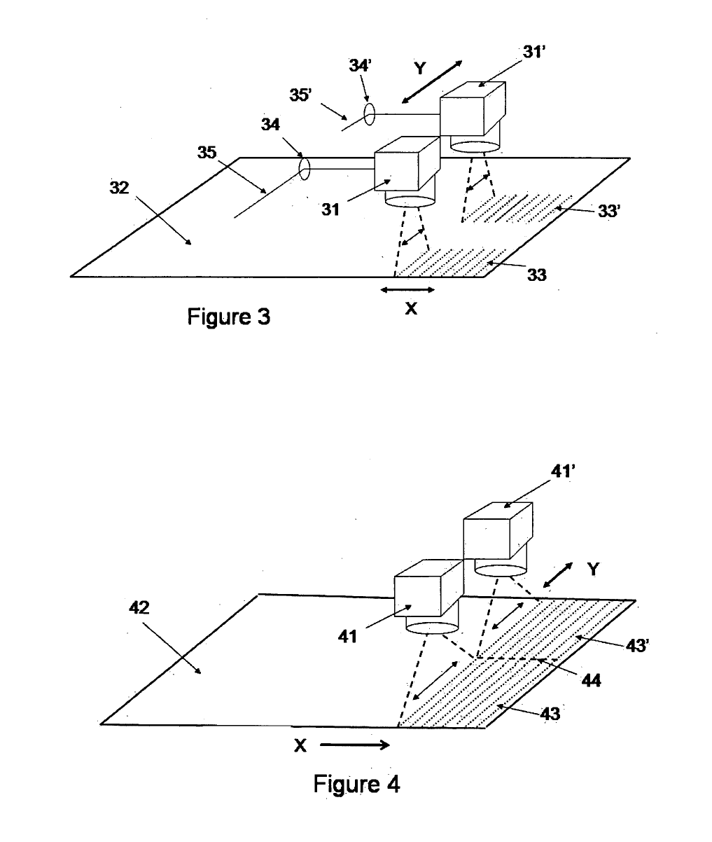

### FIG. 3

FIG. 3 shows the case where two 2D scanner and lens units 31, 31′ are mounted on a moving carriage on a gantry over the panel 32 and are used in parallel while the panel is moved continuously to create 2 separated bands of lines of holes 33, 33′. Mirrors 34, 34′ direct laser beams 35, 35′ to the scanner heads. In the case shown the laser units are stationary and the mirrors are attached to the scanner carriage so that they move when the scanners move. In the same way as described above one motion axis of the scanner unit is used to move the beam in the Y direction creating a row of holes that in the case shown extend over only a fraction of the width of the panel. The second motion axis of the scanner unit is used to cause the beam to follow the movement of the panel in the X direction during each Y scan and at the end of each Y scan is used to move the beam quickly to the start position of the next line of holes. After the full length of the panel has been processed the scanner carriage is stepped in the Y direction by the width of the bands and the motion of the panel in the opposite X direction restarted to allow further abutting bands of lines of holes to be created. The process repeats until the full area or some selected part area of the panel area has been covered with holes.

### FIG. 4

FIG. 4 shows the case that is similar to that shown in FIG. 3 where two 2D scanner and lens units 41, 41′ are mounted on a gantry over the panel 42 and are used in parallel while the panel is moved continuously to create 2 separated bands of lines of holes 43, 43′. In the same way as described above one motion axis of each scanner unit is used move the beam in the Y direction creating a row of holes while the second motion axis of the scanner unit is used to cause the beam to follow the movement of the panel in the X direction during each Y scan and at the end of each Y scan is used to move the beam quickly to the start position of the next line of holes. In the case shown, the width of the bands of lines of holes created by each scanner extends over half the width of the panel so that the two scanners can cover the full panel width without any requirement to move the scanners or panel in the Y direction After the full length of the panel has passed under the scanner heads the full area or some selected part area of the panel area has been covered with holes. This arrangement is favourable as the scanners remain stationary and only one axis of motion of the panel is required

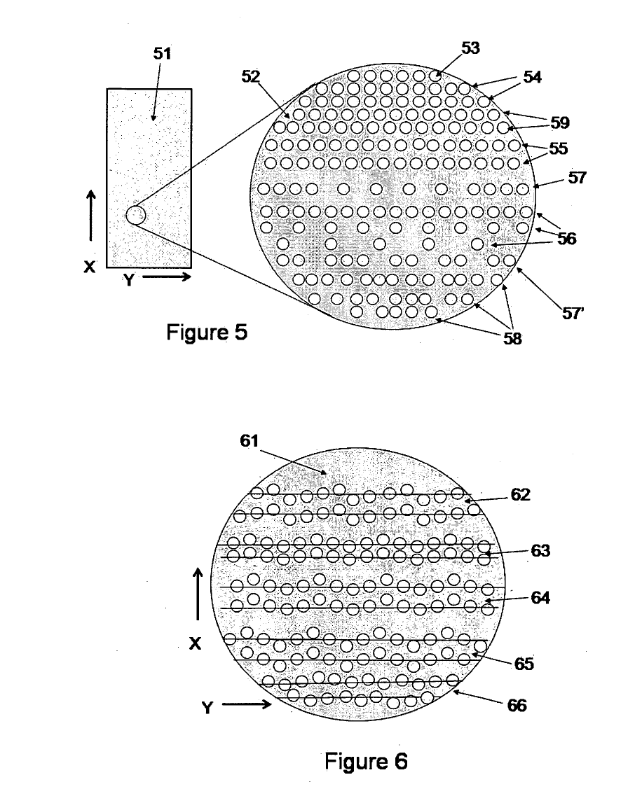

### FIG. 5

FIG. 5 shows a solar panel 51 that has been covered with holes made in the opaque coatings using a laser system as described above. An area of the solar panel has been enlarged 52 to show the detail of the holes 53 created. In the case shown straight lines of identical diameter round holes in the opaque coating have been created by a laser beam scanned in the Y direction while the panel is moving in the X direction so that lines of parallel holes are created as shown. In the enlarged area shown, the pitch and position of the holes is varied along the beam movement direction Y and the pitch between lines in the X direction is also changed so that the optical transmission varies in 2 directions. For some lines 54 the pitch in both directions is held constant to create a regular 2D array of holes. Other lines 55 also form a regular 2D array but in this case the pitch has been increased compared to lines 54 by increase of beam scan speed or reduction in laser repetition rate. Other lines 56 demonstrate a graded variation in transmission. The 3 lines shown all have different hole pitches along the Y direction while the pitch between lines in the X direction is held constant. Lines 57 and 57′ demonstrate the situation where the laser repetition rate or scan speed is varied during the scan in the Y direction leading to variations in the hole pitch along the line. The production of holes with random spacing along each line and between lines is demonstrated by lines 58. To achieve the highest density of round holes requires the use of a 2D array where there is a half pitch offset between the holes in one row and the next as shown by lines 59.

### FIG. 6

FIG. 6 shows an enlarged area 61 of a portion of a solar panel to show the detail of the holes created. In the case shown lines of identical diameter round holes in the opaque coating have been created by a laser beam scanned in the Y direction while the panel is moving in the X direction so that lines of parallel holes are created as shown. In the enlarged area shown the pitch of the holes along the beam movement direction Y is held constant while the second axis of the scanner has been used during each line scan to move the beam by small amounts in the X direction in order to create lines of holes that are not straight. Four pairs of lines 62, 63, 64, 65 are shown to demonstrate some of the possible hole configurations that can be created where the hole offsets from the centre line repeat with some regular period along the line in the Y direction. Fully randomized or wobble type motion of the beam in the X direction by use of the secondary axis of the scanner leads to randomized positioning of holes and lines 66 that wobble. From this discussion it can be seen that with a 2 axis scanner system to move the beam in both axes and with the addition of control of beam speed and laser repetition rate placement of holes at almost any location on the panel is possible.

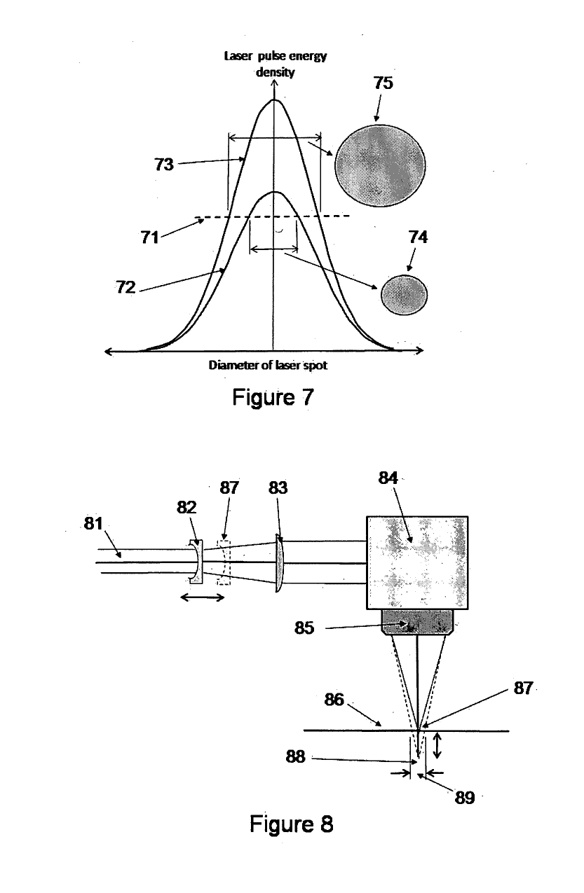

### FIG. 7

FIG. 7 shows the typical pulse energy density profile in the spot created on the surface of a solar panel when the laser beam focussed is focussed onto it. Horizontal line 61 marks the energy density level at which the opaque films are removed by ablation in one laser pulse. Curve 62 represents the energy density profile created by a pulse of low energy while curve 63 represents the energy density profile created by a pulse of higher energy. The hole created by the low energy pulse 64 has a significantly smaller diameter compared to the hole created by the higher energy pulse 65 due to the larger area of the beam that exceeds the hole ablation threshold for the latter case. Hence it can be readily seen that by variation of the total energy in the pulse the size of the beam that exceeds the threshold for ablation of the opaque coatings can be controlled and hence the size of the holes created can be adjusted.

### FIG. 8

FIG. 8 shows an optical arrangement for controlling the laser spot size on the substrate surface. The beam from a laser 81 passes through a beam expansion telescope consisting of a negative lens 82 and a positive lens 83. The negative lens is movable along the beam direction. After passing through a scanner 84 or other beam deflection optics the laser beam is focussed by a lens 85 onto the surface of the substrate 86. At the focus 87 the beam size is the minimum possible set by the laser beam divergence and the lens focal length. When the negative lens is moved to a new position 87 that is closer to the positive lens then the beam focus is caused to move further from the focus lens to a position 88 below the substrate surface. When the focus moves below the substrate surface the beam size on the substrate surface 89 increases in size and becomes greater than the minimum value achieved when the focus is on the substrate surface. In a similar way when the negative lens is moved further from the positive lens then the beam focus is caused to move closer to the focus lens and the beam size on the substrate surface also increases. Hence it can be readily seen that controlled movements of the negative lens with respect to the positive lens can be used to accurately control the laser beam spot size and the size of holes formed in the opaque coatings.

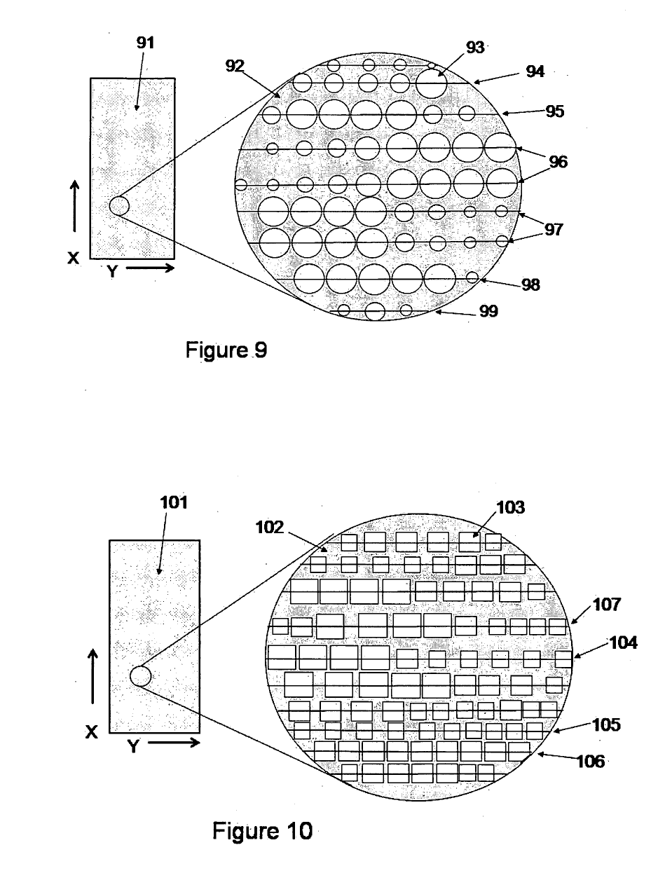

### FIG. 9

FIG. 9 shows a solar panel 91 that has been covered with holes made in the opaque coatings using a laser system as described above. An area of the solar panel has been enlarged 92 to show the detail of the holes 93 created. In the case shown straight lines of round holes in the opaque coating have been created by a laser beam scanned in the Y direction while the panel is moving in the X direction so that lines of parallel holes are created as shown. As the beam is scanned along each line in the Y direction the hole size is changed either by changing the laser energy alone or changing the laser beam spot size on the panel and simultaneously adjusting the laser pulse energy to keep the energy density constant. In the enlarged area shown the pitch and position of the holes is held constant along the beam movement direction Y while the hole size is changed. In addition the pitch between lines in the X direction is changed so that the optical transmission varies in 2 directions. In practice additional adjustments to the hole positions in the Y direction can be made by changing either the laser repetition rate or the beam speed or both of these. Additional adjustments can also be made to the hole positions in the X direction by using the secondary scanner axis in order to make lines of holes that are not straight.

### FIG. 10

FIG. 10 shows a solar panel 101 that has been covered with holes made in the opaque coatings using a laser system operating in aperture projection mode rather than focus mode as described above. An area of the solar panel has been enlarged 102 to show the detail of the holes 103 created. In the case shown straight lines of square holes of different size have been created in the opaque coating by a laser beam scanned in the Y direction while the panel is moving in the X direction so that lines of parallel holes are created as shown. To create the square holes a square aperture is placed in the beam on the laser side of the lens and the substrate arranged to be at the image plane of the lens such that a reduced image of the aperture is created on the substrate surface. The aperture unit is controllable in size in order to form holes of different size. In the enlarged area shown the pitch and position of the holes is varied along, the beam movement direction Y and the pitch between lines in the X direction is also changed so that the optical transmission varies in 2 directions. For some lines 104 the pitch is held constant while the hole size changes. For other lines 105 the hole size is held constant while the pitch is changed by change of beam scan speed or laser repetition rate. For other lines 106 the pitch and size are both held constant. For other lines 107 the hole pitch and size are both varied. In practice additional adjustments can also be made to the hole positions in the X direction by using the secondary scanner axis in order to make lines of holes that are not straight.

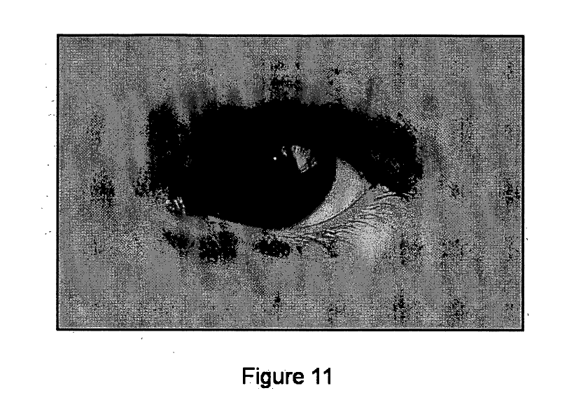

### FIG. 11

FIG. 11 shows a partially transparent solar panel 111 superimposed on which is a half tone partially transparent image 112 formed by ablating holes in the opaque coatings that are too small for the human eye to resolve such the transparency varies in 2 dimensions due to variations in the size, pitch and position of holes such that the optical transmission is varied in 2 directions.

The invention described above thus provides a method for forming partially transparent thin film solar panels in which a dense array of small unconnected holes is formed in the opaque coating and where the holes are sufficiently small that they are not discernable to the human eye and where the light transparency factor caused by the holes is able to be graded in all directions in by means of: a pulsed laser beam that is focussed or imaged onto the panel surface by a suitable lens system to form the holes in the opaque film or films by a process of laser ablation, motion of the laser beam over the surface of the panel in a line in a first axis, formation of the holes in the opaque film or films with a single pulse from the laser with the beam (or panel) in continuous motion, causing the pitch of the holes along the first axis to vary by changing the laser repetition rate or by changing the speed of the beam motion with respect to the panel or by changing both, firing the pulses from the laser at such a rate that holes created along the first axis never touch or overlap, motion of the laser beam over the panel surface in a second axis that is close to perpendicular to the first axis, changing the pitch between the lines of holes created along the first axis by varying the movement of the beam with respect to the panel in the second axis so that holes created along one line never touch or overlap those in an adjacent line.

In a preferred method all the holes are round or close to round and are formed with an optical system that focuses the laser beam onto or close to the substrate surface.

In a preferred method the size of the holes created with each laser pulse can be changed by varying the energy in the pulse.

In a preferred method the changing of the size of the holes created with each laser pulse is caused by moving the focus of the laser beam with respect to the substrate surface so that the size of the laser beam incident on the substrate changes while simultaneously keeping the energy density in the spot constant by controlling the laser power.

In a preferred method the change of position of the focus of the laser beam with respect to the solar panel surface is accomplished by means of a dynamically adjustable telescope placed before the focussing lens.

In a preferred method the change of position of the focus of the laser beam with respect to the solar panel surface is accomplished by mounting the focus lens on a controlled stage that causes the separation between the lens and the panel to be rapidly changed.

In a preferred method the holes can have any desired shape and the shape is created by means of a special optical beam reshaping system or aperture unit placed before the focusing lens which forms a beam of the required shape at some intermediate plane before the focussing lens which is then used in imaging mode to form a reduced size image of the beam at the intermediate plane on the surface of the substrate.

In a preferred method the size of the spot formed on the substrate surface is varied by changing the size of the beam formed at the intermediate plane by either by adjustment of the special optical device or by adjustment of the aperture size while simultaneously keeping the energy density in the spot constant by controlling the laser power.

In a preferred method the position of the holes forms a regular repeating 2D array with constant hole pitch in both axes.

In a preferred method the position of the holes forms an irregular 2D array where the pitch of the holes varies in one or both axes.

In a preferred method the positions of the holes are randomly placed with respect to each other.

In a preferred method a single laser beam is used to create a line of holes across the full width of the solar panel in the first axis direction.

In a preferred method multiple laser beams are used to complete a full line across the panel in the first axis direction.

In a preferred method an optical scanner unit is used to move the beam at high speed in the direction of the line of holes parallel to the first axis and the panel is moved in steps in the second axis direction.

In a preferred method the optical scanner unit has 2 axes of motion and the panel is moved continuously in the second axis direction and the first motion axis of the scanner is used to move the beam in the first axis direction creating a straight row of holes while the second motion axis of the scanner unit is used to cause the beam to follow the movement of the panel in the second axis direction during each first axis scan and at the end of each first axis scan is used to move the beam quickly to the start position of the next line of holes.

In a preferred method the second axis of the scanner is moved in a controlled way during each first axis scan to create lines of holes that are not in a straight line.

In a preferred method the laser is incident on the side of the solar panel that has the active coatings and causes a hole to be made in the opaque films.

In a preferred method the laser is incident on the opposite side of the solar panel to the one having the active coatings and the beam passes through the panel substrate before impinging on the opaque coatings and removing them to form a hole.

In a preferred method holes are made in the opaque, coating over only a part of the area of the solar panel in order to create a region of optical transparency for aesthetic purposes.

In a preferred method holes are made over the full area of the solar panel in order to establish a level of optical transparency so that the panel can function as a-useful window or roof light.

In a preferred method holes are made in the opaque coatings where a region of higher optical transparency is superimposed on a background region of lower optical transparency such that the panel an operate as an effective window and also have aesthetic functionality.

In a preferred method the optical transmission of a solar panel varies in a graded way in 2 dimensions in order to create a 2D half tone type image.

The invention described above also provides a laser ablation tool for carrying out the methods described above and a solar panel formed by the method.

The invention thus provides a method of using a laser to make partially transparent thin film solar panels by the process of ablating dense arrays of microscopic holes in an opaque layer of the panel. The holes are too small to be individually discerned by the naked human eye and are created in the form of regular or irregular arrays in which the holes vary in size, shape and position in order to form areas on the solar panel where the optical transparency varies in 2 dimensions. With such a method it is possible to form solar panels that have either uniform partial transparency over the whole surface, have local areas where half tone partially transparent images are formed on an opaque background or have half tone images superimposed on a partially transparent background.

1. A method for forming a partially transparent thin film solar panel by providing an array of unconnected holes in an opaque layer of the panel the holes being sufficiently small so that they are not discernable to the human eye and the light transparency factor caused by the holes being selectively controlled so that it can be graded in two dimensions by varying the size and/or spacing of the holes.

2. A method as claimed in claim 1 in which the holes are formed by means of a pulsed laser beam that is focussed or imaged onto the opaque layer, each hole being formed by a single laser pulse.

3. A method as claimed in claim 1 in which the laser beam is scanned relative to the panel and the spacing of the holes is varied by changing the laser repetition rate and/or the scanning speed.

4. A method as claimed in claim 3 in which the holes are formed in an array of lines, the light transparency factor being graded by varying the spacing between adjacent holes in a line and/or by varying the spacing between the lines.

5. A method as claimed in claim 1 in which the laser beam is scanned relative to the panel and the size of the holes is varied by changing the laser pulse energy and/or the focussing of the pulses on the opaque layer.

6. A method as claimed in claim 1 in which the transparency factor is graded in two dimensions so as to form a half tone image on the panel.

7. A method as claimed in claim 1 in which the panel comprises a plurality of interconnected solar cells, the variations in light transparency factor across each cell being arranged such that the electrical performance of each cell is within a predetermined range compared to the other cells.

8. A method as claimed in claim 6 in which a half tone image extends across a plurality of the cells and additional transparency is provided in cells on which darker and/or fewer parts of the image lie so that the electrical performance of each cell is within said predetermined range.

9. A thin film solar panel having an opaque layer which is made partially transparent by providing an array of unconnected holes therein, the holes being sufficiently small so that they are not discernable to the human eye and the light transparency factor caused by the holes being graded in one or two dimensions by variations in the size and/or spacing of the holes.

10. A solar panel as claimed in claim 9 in which the holes are provided in an array of lines, the light transparency factor being graded by variations in the spacing between adjacent holes in a line and/or by variations in the spacing between the lines.

11. A solar panel as claimed in claim 9 in which the light transparency factor is graded in two dimensions so as to provide a half tone image on the panel.

12. A solar panel as claimed in claim 9 in which the panel comprises a plurality of interconnected solar cells, the variations in light transparency factor across each cell being arranged such that the electrical performance of each cell is within a predetermined range compared to the other cells.

13. A solar panel as claimed in claim 11 in which a half tone image extends across a plurality of the cells and additional transparency is provided in cells on which darker and/or fewer parts of the image lie so that the electrical performance of each cell is within said predetermined range.

14. A laser ablation tool for forming a partially transparent thin film solar panel by forming an array of unconnected holes in an opaque layer of the panel the holes being sufficiently small so that they are not discernable to the human eye, the tool comprising a laser, a scanner for scanning a laser beam relative to the panel, focussing means for focussing the laser beam on the opaque layer and control means for selectively controlling the laser repetition rate, the scanning speed, the pulse energy and/or the focussing of the laser beam whereby the light transparency factor caused by the holes can be graded in two dimensions by varying the size and/or spacing of the holes.

15. A laser ablation tool as claimed in claim 14 comprising a plurality of lasers and/or a plurality of scanners which are operable together to increase the speed at which the array of holes can be formed in the panel or to reduce the scanning speed required to form the array of hole within a given time.
